(19) United States
(12) Patent Application Publication
(10) Pub. No.: US 2012/0015458 A1
(43) Pub. Date: Jan. 19, 2012

(54) MOUNTING APPARATUS AND MOUNTING METHOD

(76) Inventors: Takayoshi Akamatsu, Shiga (JP); Katsumi Terada, Shiga (JP); Hajime Hirata, Shiga (JP)

(21) Appl. No.: 13/260,232

(22) PCT Filed: Mar. 18, 2010
(86) PCT No.: PCT/JP2010/054652

§ 371 Date: Sep. 23, 2011

(30) Foreign Application Priority Data
Mar. 23, 2009 (JP) 2009-069412

(51) Int. Cl. H01L 21/58; B23P 19/00

(52) U.S. Cl. 438/15; 29/740; 257/E21.499

(57) ABSTRACT

Provided is a mounting apparatus which mounts a chip component on a circuit pattern on a circuit board having a plurality of circuit patterns formed thereon. The mounting apparatus is provided with a plurality of bonding tools each of which mounts the chip component on each of the circuit patterns on the circuit board. Each bonding tool is provided with, within a region on the circuit board where the chip component is to be mounted, an exclusive mounting region where only each bonding tool can mount the chip component, and a common mounting region where both the bonding tool and the adjacent bonding tool can mount the chip component. A mounting method is also provided. The mounting tact time of the chip components can be shortened even in case where a plurality of circuit patterns are formed on the circuit board and a failure circuit pattern is included among the circuit patterns which have been formed.

### TECHNICAL FIELD OF THE INVENTION

The present invention relates to a mounting apparatus and a mounting method for mounting a chip component such as an integrated circuit element on a circuit board.

### BACKGROUND ART OF THE INVENTION

Recently, accompanying with lightening and miniaturization of an electronic product, it has been developed that a pattern of a circuit board is made at a fine pitch (high-accuracy and fine condition). As a technology for dealing with this, a technology is proposed wherein a flexible film substrate is formed by forming a very fine circuit pattern on a flexible film applied onto a reinforced plate having an excellent dimensional stability using an adhesive material capable of being delaminated, and a chip component is mounted thereon to make a circuit board (for example, Patent document 1).

### PRIOR ART DOCUMENTS

### Patent Documents

Patent document 1: JP-A-2003-298194

### SUMMARY OF THE INVENTION

### Problems to be Solved by the Invention

Because such a flexible film substrate varies in dimension depending upon temperature and humidity, a chip component is mounted before the flexible film substrate formed with a fine circuit pattern is delaminated from the reinforced plate.

On the other hand, in an exposure process in which a circuit pattern is formed on a flexible film, there is a case where the exposure of the circuit pattern is not performed normally by dust present in the exposure unit, etc., and a failure may be caused in a part of circuit patterns. Further, if a resist to be applied on the flexible film is not sufficiently stuck to the flexible film before exposure, a part of circuit patterns may appear as a failure by etching after exposure.

Therefore, a flexible film substrate having finished the exposure process and the processing process following thereto is inspected in an inspection process with presence of failure of each circuit pattern. At that time, a bad mark may be labeled to the position of the failure circuit pattern, or the state of the failure is recorded in process control data.

In a process for mounting chip components on circuit patterns, mounting of a chip component is carried out confirming this bad mark or the process control data. The chip component is mounted on a normal circuit pattern, and not mounted on a failure circuit pattern. The failure circuit pattern occurs irregularly.

If chip components are mounted on such a circuit board using a conventional mounting apparatus (an apparatus wherein a chip component and a circuit pattern of a circuit board are aligned to each other and chip components are mounted on circuit patterns one by one by a bonding tool), the treatment for skipping the failure circuit pattern becomes complicated, and it becomes difficult to shorten the mounting tact time.

Further, even if chip components are tried to be mounted by a plurality of bonding tools in order to shorten the mounting tact time, because the plurality of bonding tools try mounting for a single circuit board, an waiting time due to interference at the time of operation occurs, and the operation for mounting cannot proceed efficiently. In particular, in case where a failure circuit pattern is included in a circuit board, operation interference is liable to occur and the efficiency for mounting cannot be improved.

On the other hand, as to the mounting time of chip components, included are a time for carrying a chip component from a supply section of chip components to a bonding tool, a time required for alignment between a chip component and a circuit pattern, a time for mounting a chip component on a circuit pattern by pressing and heating, etc. In particular, the time for carrying the chip component occupies a great rate among the entire mounting time. Therefore, in case where chip components are mounted by a plurality of bonding tools, unless it is tried not to generate a waiting time during the time for carrying chip components, a problem may be caused wherein the entire mounting tact time cannot be shortened. Namely, the mounting tact time cannot be shortened merely by increasing the number of bonding tools.

Accordingly, an object of the present invention is to provide a mounting apparatus and a mounting method wherein a plurality of circuit patterns are formed on a circuit board, and even if a failure circuit pattern is included in the formed circuit patterns, the mounting tact time for chip components can be shortened.

### Means for Solving the Problems

To achieve the above-described object, provided is the invention according to claim 1, and the invention is a mounting apparatus for mounting a chip component on a circuit pattern on a circuit board having a plurality of circuit patterns formed thereon, characterized in that a plurality of bonding tools, each of which mounts a chip component on each of the circuit patterns on the circuit board, are provided, and each bonding tool has, within a region on the circuit board where the chip component is to be mounted, an exclusive mounting region where only each bonding tool can mount the chip component and a common mounting region where both each bonding tool and an adjacent bonding tool can mount the chip component.

The invention according to claim 2, in the invention according to claim 1, is a mounting apparatus wherein a failure circuit pattern in which a circuit pattern becomes a failure and a normal circuit pattern in which a circuit pattern is normal are included in the plurality of circuit patterns formed on the circuit board, and each bonding tool has a function for mounting a chip component only on the normal circuit pattern on the circuit board based on information of the failure circuit pattern detected in advance.

The invention according to claim 3, in the invention according to claim 2, is a mounting apparatus wherein a function is provided wherein the exclusive mounting region and the common mounting region of each bonding tool are calculated from a positional information of the failure circuit pattern among the plurality of circuit patterns formed on the circuit board, and a chip component is mounted only on the normal circuit pattern on the circuit board based on an information of the calculated exclusive mounting region and common mounting region.

The invention according to claim 4, in the invention according to claim 2 or 3, is a mounting apparatus wherein a carrier means is provided which, during a time when any of the plurality of bonding tools is mounting a chip component on the normal circuit pattern, supplies a chip component to any of remaining bonding tools among the plurality of bonding tools or supplies chip components to the remaining bonding tools.

The invention according to claim 5, in the invention according to any of claims 1 to 4, is a mounting apparatus wherein a height detection means for detecting a mounting height of a chip component mounted on the circuit board is provided to each bonding tool, and a function is provided wherein mounting heights of all chip components mounted on the circuit board are determined by the height detection means and dispersion of the mounting heights is calculated.

The invention according to claim 6, in the invention according to any of claims 1 to 5, is a mounting apparatus wherein a function is provided wherein mounting positions of all chip components mounted on the circuit board are memorized, and the mounting positions and number of the chip components mounted on the circuit board and positions and number being unmounted are calculated.

The invention according to claim 7 is a mounting method for mounting a chip component on a circuit pattern on a circuit board formed with a plurality of circuit patterns using a plurality of bonding tools, wherein an exclusive mounting region where only each bonding tool can mount the chip component and a common mounting region where both each bonding tool and an adjacent bonding tool can mount the chip component are provided on the circuit board, and a failure circuit pattern in which a circuit pattern is a failure and a normal circuit pattern in which a circuit pattern is normal are included in the plurality of circuit patterns formed on the circuit board, and the mounting method comprises the steps of:

a step at which each bonding tool starts to out a chip component onto a normal circuit pattern within the exclusive mounting region; and

a step at which a chip component is mounted onto a normal circuit pattern within the common mounting region in order from a bonding tool which has finished mounting of a chip component onto a normal circuit pattern within each exclusive mounting region.

The invention according to claim 8, in the invention according to claim 7, is a mounting method further comprising:

a step at which a positional information of the failure circuit pattern among the plurality of circuit patterns formed on the circuit board is memorized in advance as a failure circuit pattern information; and

a step at which the exclusive mounting region and the common mounting region of each bonding tool are calculated based on the failure circuit pattern information.

The invention according to claim 9, in the invention according to claim 7 or 8, is a mounting method wherein a step is performed in parallel at which, during a time when any of the plurality of bonding tools is mounting a chip component on the normal circuit pattern, a chip component is carried to any of remaining bonding tools among the plurality of bonding tools or chip components are carried to the remaining bonding tools.

The invention according to claim 10, in the invention according to any of claims 7 to 9, is a mounting method wherein a height detection means for detecting a mounting height of a chip component mounted on the circuit board is provided to each bonding tool, and the mounting method further comprises:

a step for determining mounting heights of all chip components mounted on the circuit board using the height detection means; and

a step for calculating dispersion of the mounting heights detected by the height detection means.

The invention according to claim 11, in the invention according to any of claims 7 to 10, is a mounting method further comprising:

a step for memorizing mounting positions of all chip components mounted on the circuit board; and

a step for calculating the mounting positions and number of the chip components mounted on the circuit board and positions and number being unmounted.

### Effect According to the Invention

In the invention according to claim 1, a plurality of bonding tools are provided, and further, an exclusive mounting region where only each bonding tool can mount the chip component and a common mounting region where both of bonding tools adjacent to each other can mount the chip component are provided on the circuit board. Therefore, since each bonding tool can mount a chip component sharing the exclusive mounting region on the circuit board and can carry out mounting of a chip component on the common mounting region in order from the bonding tool which has finished the mounting on the exclusive mounting region, the mounting tact time can be shortened.

In the invention according to claim 2, the bonding tool mounts a chip component only on the normal circuit pattern on the circuit board based on the information of failure circuit pattern detected in advance. Therefore, even if a normal circuit pattern and a failure circuit pattern are disposed irregularly in circuit patterns on the circuit board, because a treatment in which mounting on a failure circuit pattern is not carried out (skip treatment) can be known in advance, the mounting tact time can be shortened.

In the invention according to claim 3, the exclusive mounting region and the common mounting region are calculated from the positional information of the failure circuit pattern, and a chip component is mounted only on the normal circuit pattern on the circuit board. Therefore, even if a normal circuit pattern and a failure circuit pattern are disposed irregularly in circuit patterns on the circuit board, because optimum exclusive mounting region and common mounting region are determined in advance, the mounting tact time can be shortened.

In the invention according to claim 4, mounting of chip components onto the circuit board can be performed efficiently, and the mounting tact time can be shortened.

In the invention according to claim 5, dispersion in thickness of all chip components on the circuit board can be determined. After the chip components are mounted on the circuit board, in the next process, a batch press for pressing a plurality of chip components simultaneously is carried out. At the time of the batch press, if a chip component whose thickness is dispersed out of an acceptable range is taken out and a new chip component is mounted (repair operation), the pressing force does not act on a part of chip components, and a good batch press can be performed.

In the invention according to claim 6, the number and the mounting positions of chip components mounted on the circuit board can be recognized. After the chip components are mounted on the circuit board, in the next process, a batch press for pressing a plurality of chip components simultaneously is carried out. At the time of the batch press, the pressing force for the chip components served to the batch press can be varied based on the number of the chip components. Therefore, even in a circuit board where a chip component is not mounted on a failure circuit pattern, the batch press can be performed at a good condition.

In the invention according to claim 7, each bonding tool starts to mount a chip component onto a normal circuit pattern within the exclusive mounting region, and a chip component is mounted onto a normal circuit pattern within the common mounting region in order from a bonding tool which has finished mounting of a chip component onto a normal circuit pattern within each exclusive mounting region. Therefore, even if a normal circuit pattern and a failure circuit pattern are disposed irregularly in circuit patterns on the circuit board, the mounting tact time can be shortened.

In the invention according to claim 8, the positional information of failure circuit pattern on the circuit board is memorized in advance. Therefore, even if a normal circuit pattern and a failure circuit pattern are disposed irregularly in circuit patterns on the circuit board, because a bonding tool can be given with a demand for operation in advance, the mounting tact time can be shortened.

In the invention according to claim 9, during a time when a bonding tool is mounting a chip component on the circuit board, at a parallel condition, a chip component is carried to a remaining bonding tool. Since the time for carrying chip components occupies a great rate among the entire mounting time, even in case where the mounting of chip components are carried out by a plurality of bonding tools, a waiting time does not occur by the time for carrying chip components, and therefore, the entire mounting tact time can be shortened.

In the invention according to claim 10, dispersion in thickness of all chip components on the circuit board can be determined. After the chip components are mounted on the circuit board, in the next process, a batch press for pressing a plurality of chip components simultaneously is carried out. At the time of the batch press, if a chip component whose thickness is dispersed out of an acceptable range is taken out and a new chip component is mounted (repair operation), the pressing force does not act on a part of chip components, and a good batch press can be performed.

In the invention according to claim 11, the number and the mounting positions of chip components mounted on the circuit board can be recognized. After the chip components are mounted on the circuit board, in the next process, a batch press for pressing a plurality of chip components simultaneously is carried out. At the time of the batch press, the pressing force for the chip components served to the batch press can be varied based on the number of the chip components. Therefore, even in a circuit board where a chip component is not mounted on a failure circuit pattern, the batch press can be performed at a good condition.

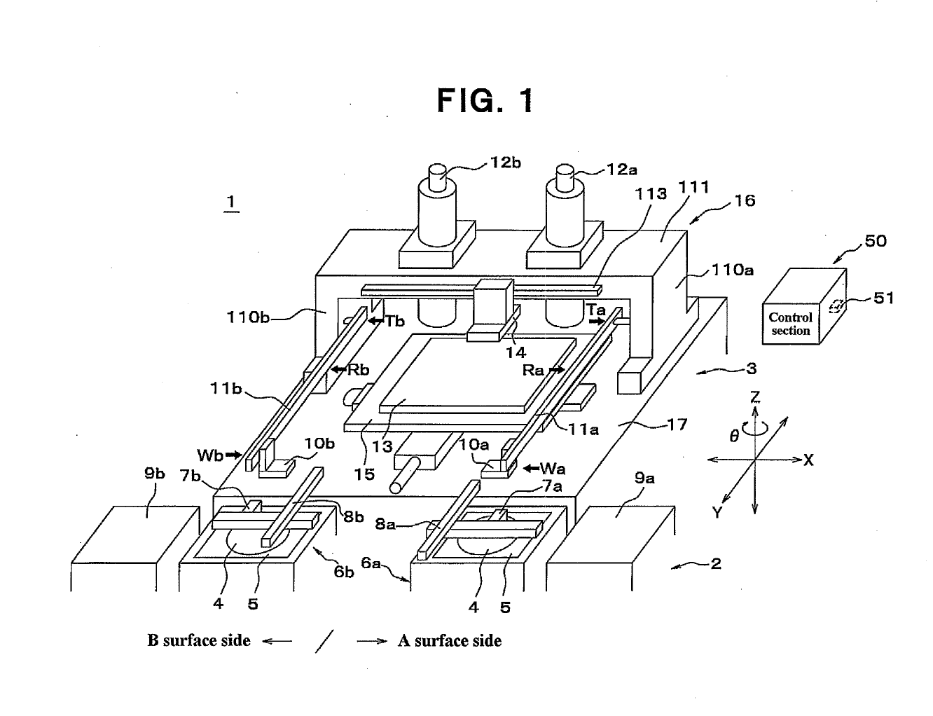

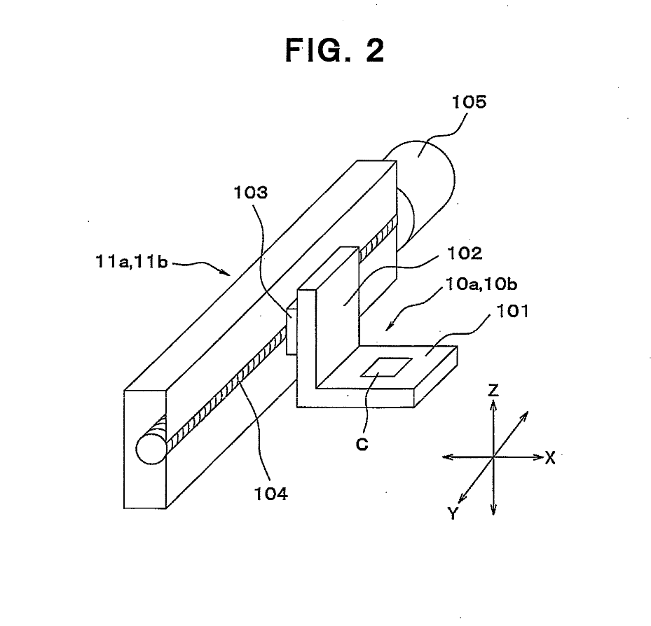

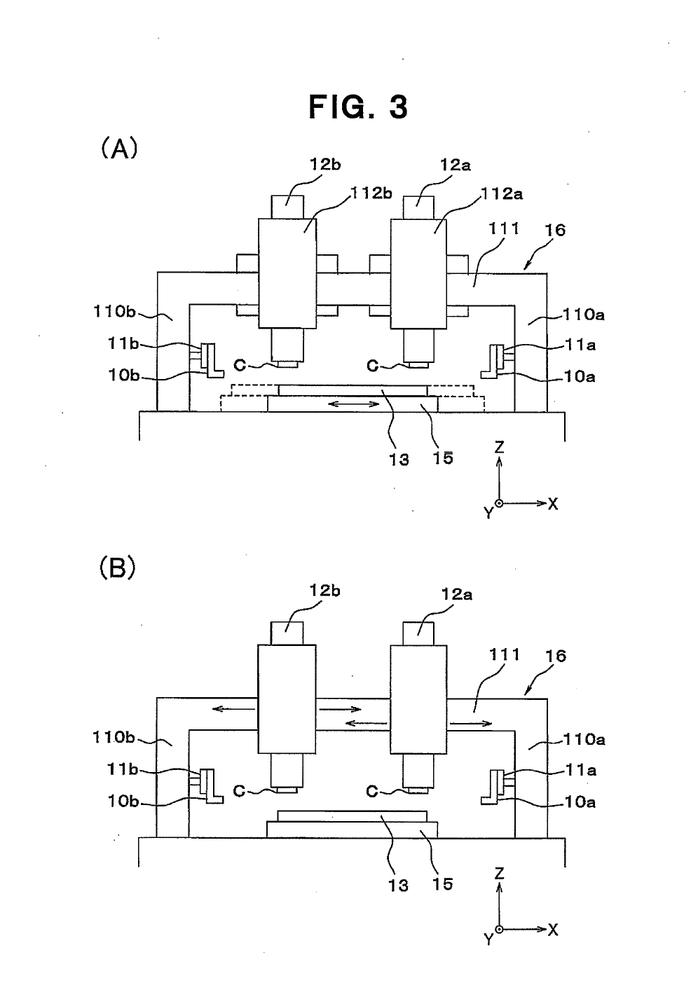

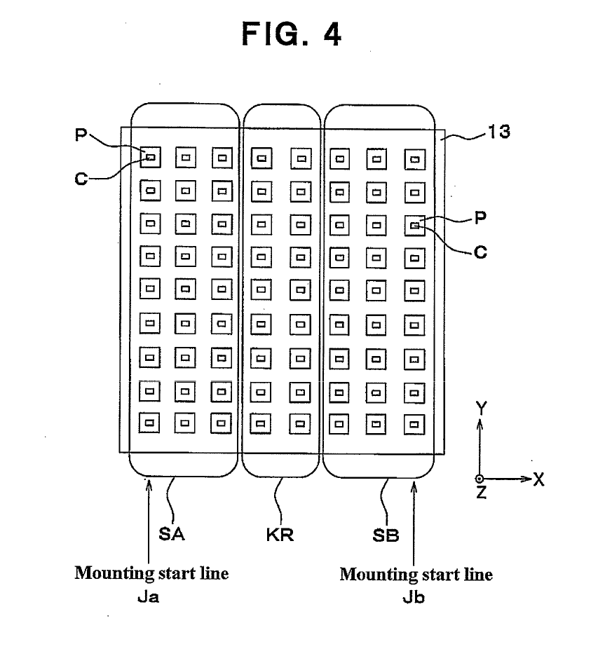

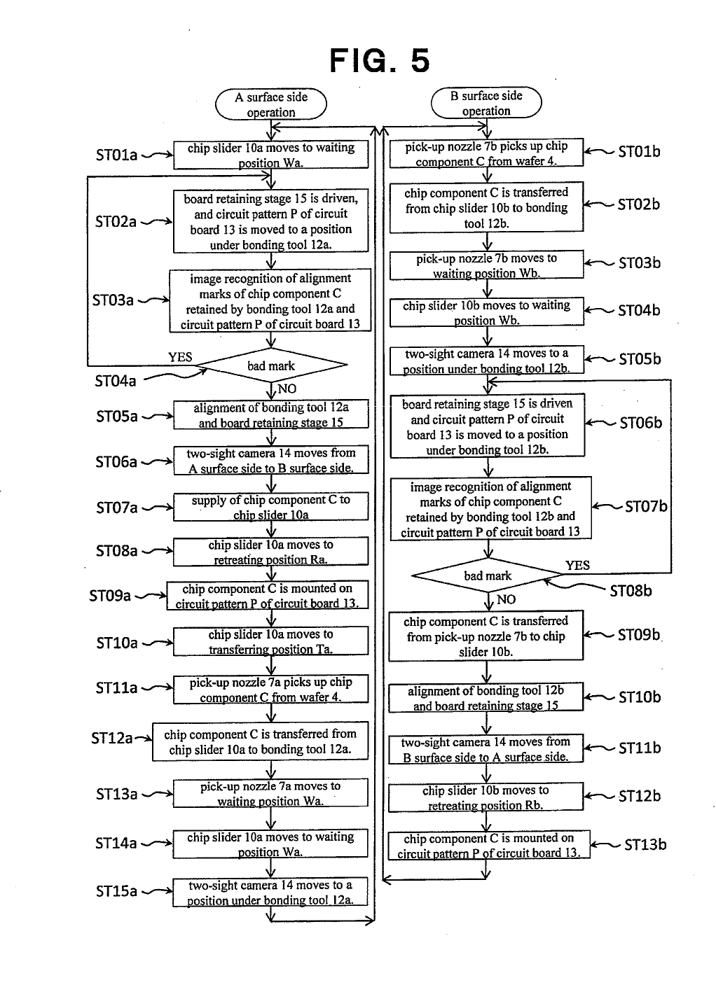

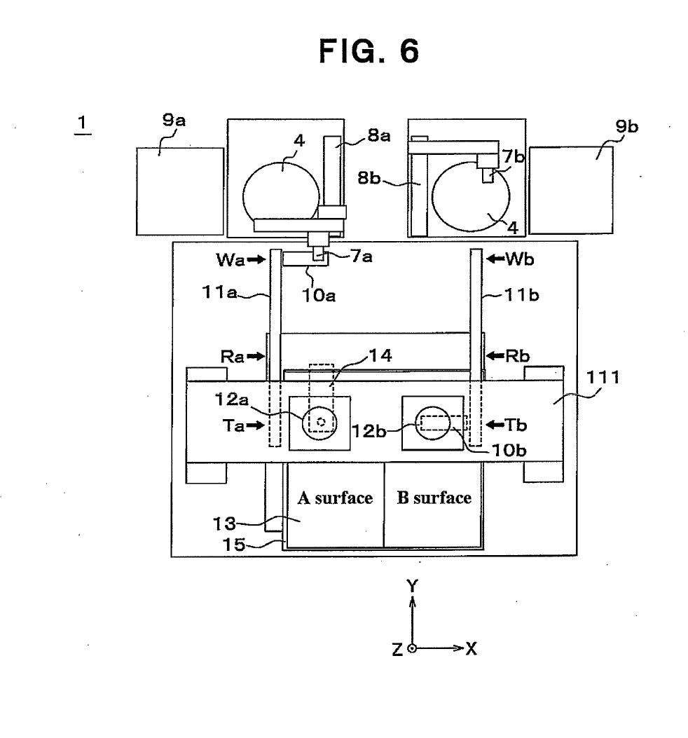

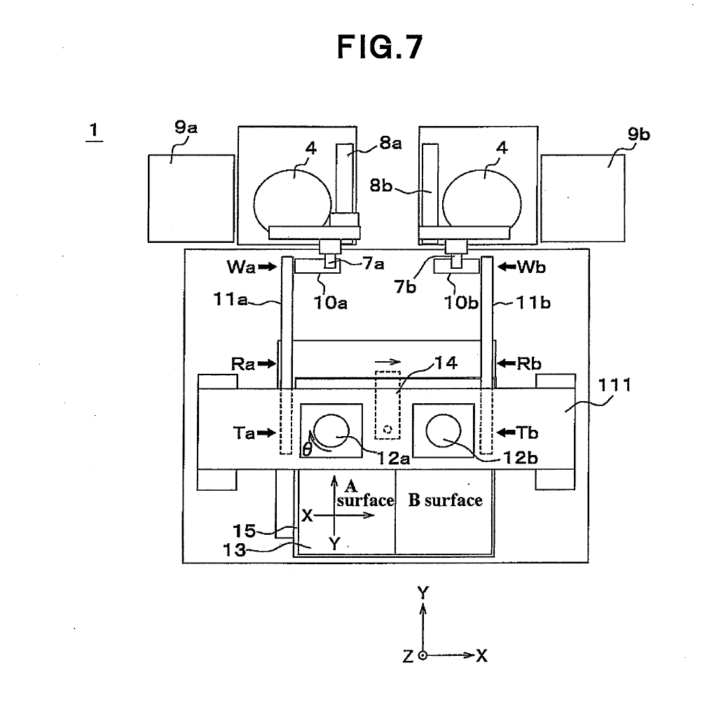

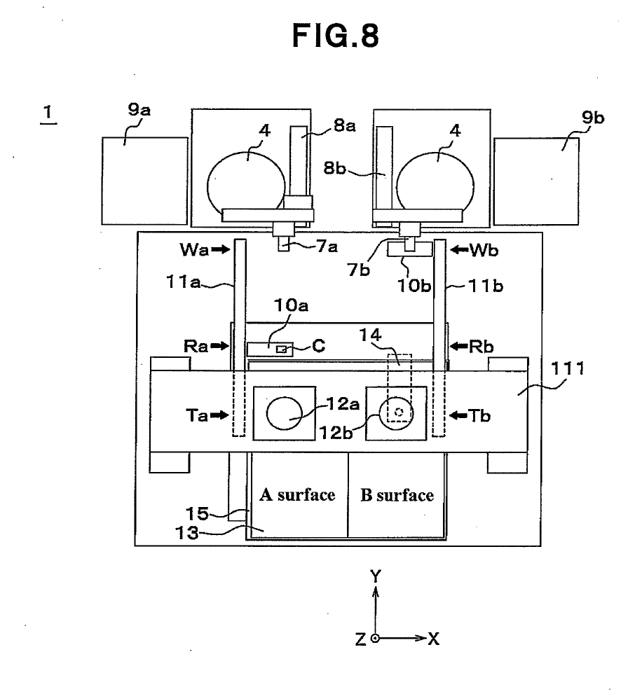

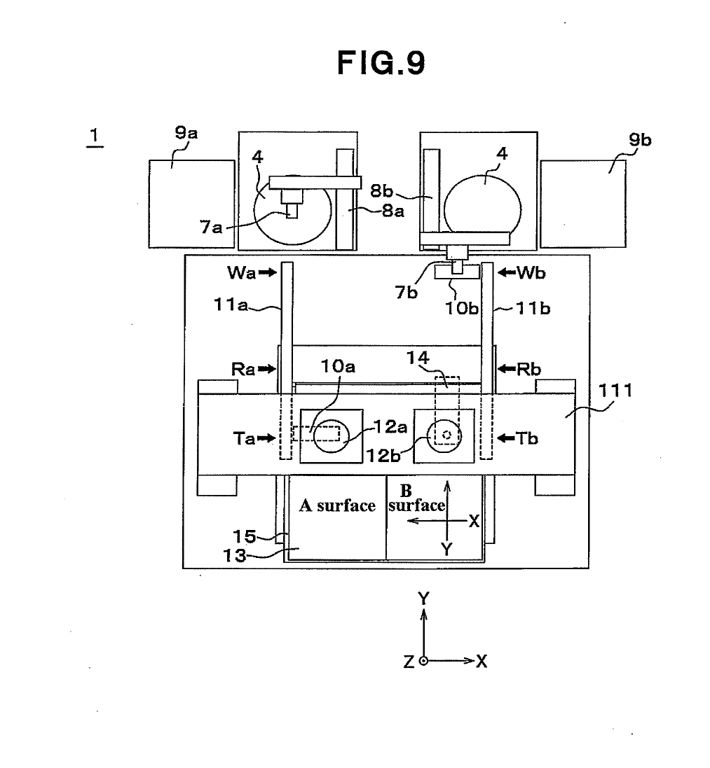

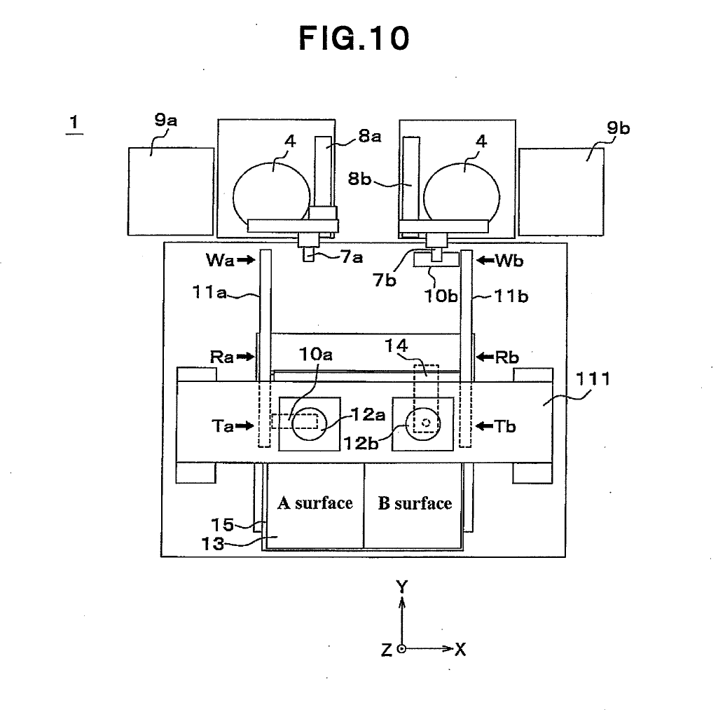

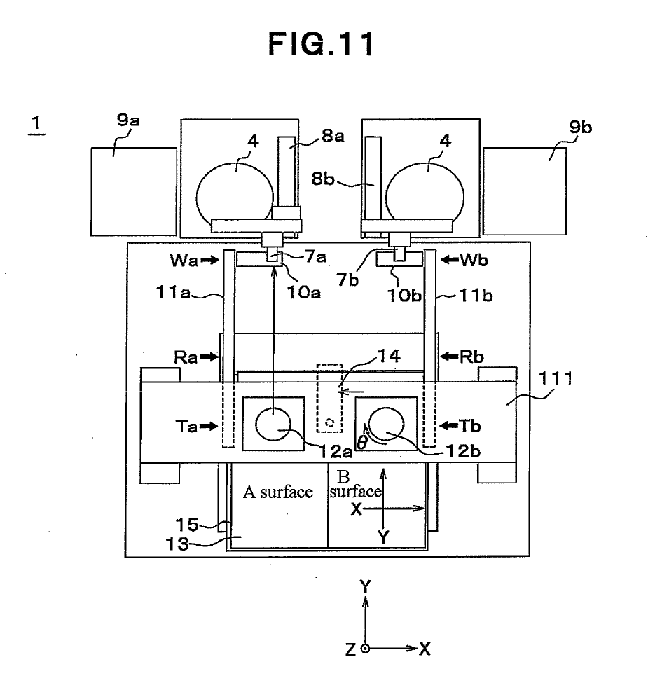

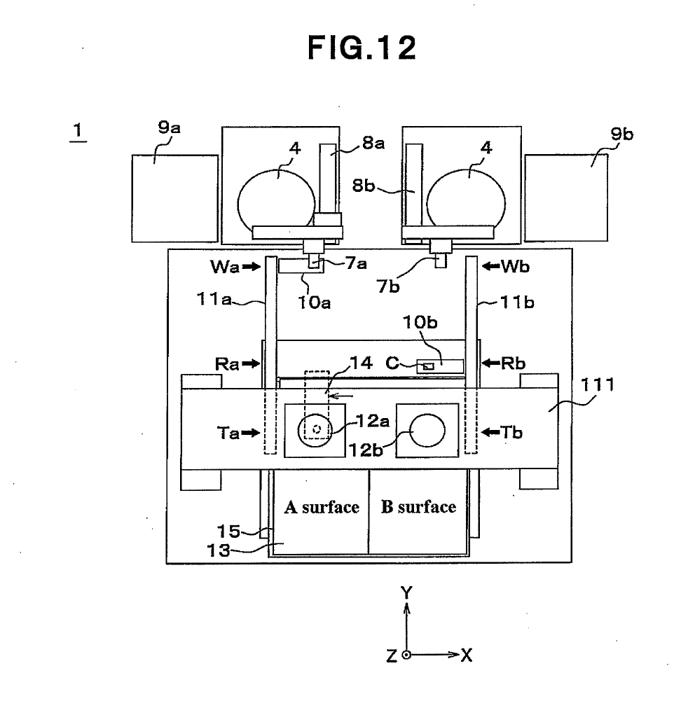

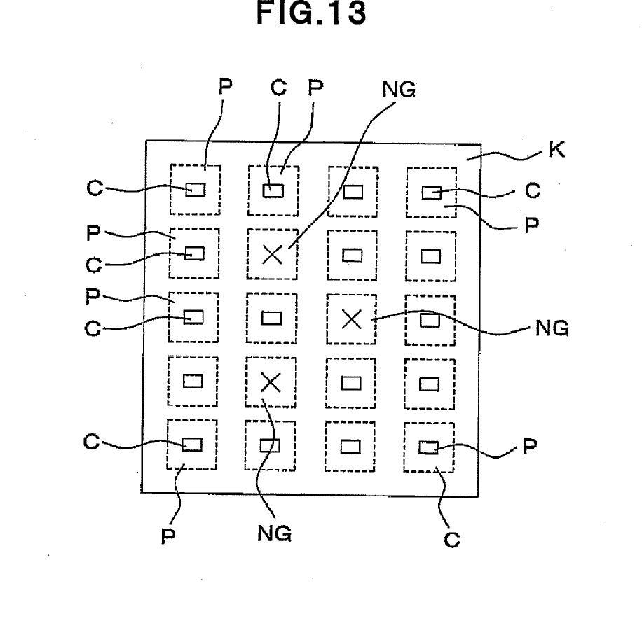

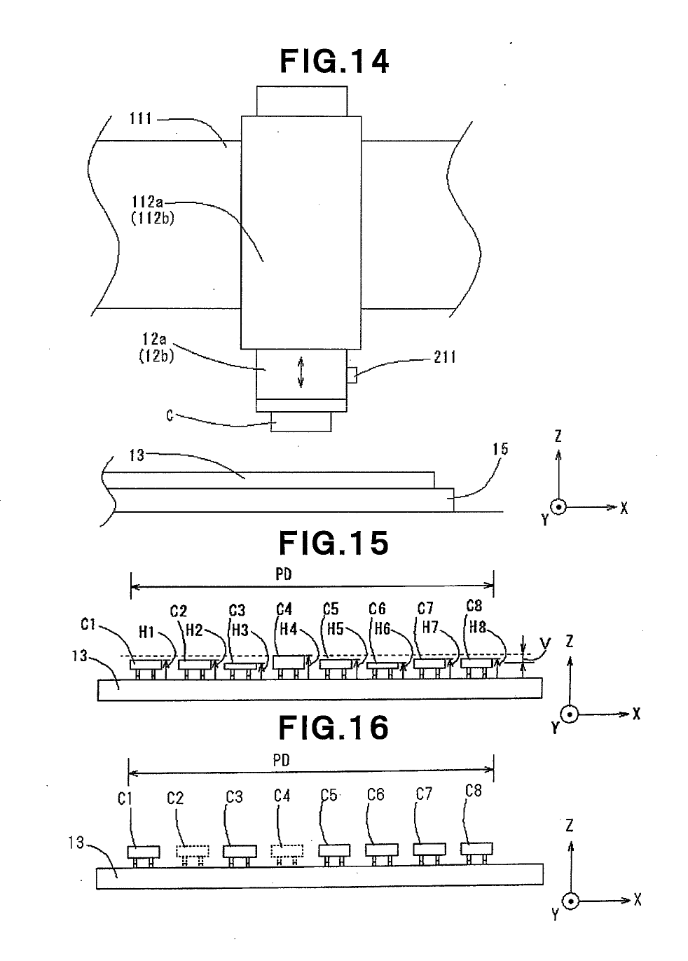

### BRIEF EXPLANATION OF THE DRAWINGS

[FIG. 1] FIG. 1 is a schematic perspective view of a mounting apparatus according to an embodiment of the present invention.

[FIG. 2] FIG. 2 is a schematic diagram of a chip slider and a carrier rail.

[FIG. 3] FIG. 3 shows a side view (A) showing a structure of bonding tools and a gantry frame and a side view (B) showing a state where bonding tools are moved horizontally.

[FIG. 4] FIG. 4 is a diagram for explaining an example of exclusive mounting region and common mounting region on a board.

[FIG. 5] FIG. 5 is a flowchart for explaining an example of operation of a mounting apparatus according to the present invention.

[FIG. 6] FIG. 6 is a diagram for explaining states of mounting apparatus 1 at steps ST01a, ST01b, ST02a, ST02b, ST03a and ST04a in the flowchart depicted in FIG. 5.

[FIG. 7] FIG. 7 is a diagram for explaining states of mounting apparatus 1 at steps ST05a, ST06a, ST07a, ST03b and ST04b in the flowchart depicted in FIG. 5.

[FIG. 8] FIG. 8 is a diagram for explaining states of mounting apparatus 1 at steps ST08a and ST09a in the flowchart depicted in FIG. 5.

[FIG. 9] FIG. 9 is a diagram for explaining states of mounting apparatus 1 at steps ST10a, ST11a, ST05b and ST06b in the flowchart depicted in FIG. 5.

[FIG. 10] FIG. 10 is a diagram for explaining states of mounting apparatus 1 at steps ST12a, ST13a, ST07b, ST08b and ST09b in the flowchart depicted in FIG. 5.

[FIG. 11] FIG. 11 is a diagram for explaining states of mounting apparatus 1 at steps ST14a, ST10b and ST11b in the flowchart depicted in FIG. 5.

[FIG. 12] FIG. 12 is a diagram for explaining states of mounting apparatus 1 at steps ST15a, ST12b and ST13b in the flowchart depicted in FIG. 5.

[FIG. 13] FIG. 13 is a diagram for explaining an example of failure circuit pattern among circuit patterns on a board.

[FIG. 14] FIG. 14 is a diagram for explaining a height detection means provided to a bonding head.

[FIG. 15] FIG. 15 is a schematic sectional view of chip components mounted on a circuit board.

[FIG. 16] FIG. 16 is a schematic sectional view for explaining an example of a state where chip components are not mounted on failure circuit patterns on a circuit board.

### EMBODIMENTS FOR CARRYING OUT THE INVENTION

Hereinafter, embodiments of the present invention will be explained referring to figures. Where, the symbols of members used in the description of the background art will be used as they are.

FIG. 1 shows a schematic perspective view of a mounting apparatus 1 according to an embodiment of the present invention. In FIG. 1, the left/right direction as viewed toward mounting apparatus 1 is referred to as X axis, the direction toward front side (this side) is referred to as Y axis, an axis perpendicular to XY plane formed by X axis and Y axis is referred to as Z axis, and the direction rotating around Z axis is referred to as θ axis. Mounting apparatus 1 approximately comprises chip component supply section 2, chip component mounting section 3, and control section 50 for carrying out control of the whole of mounting apparatus 1. In this embodiment, a case will be explained where chip component supply sections 2 and chip component mounting sections 3 are provided by two systems, respectively. In order to improve the mounting efficiency of chip components C, the number of the systems is not limited to two systems, and more systems may be provided. In explanation for same kind of members with respect to the structure of the apparatus, “a” or “b” is attached at the last position of each symbol, and the right side of mounting apparatus 1 is referred to as “A surface side” and the left side is referred to as “B surface side”. In circuit board K, as shown in FIG. 13, a failure circuit pattern NG is included at an arbitrary position.

Chip component supply sections 2 comprises pick-up stages 6a, 6b each placing magazine 5 contained with wafer 4 therein, carrier tools 8a, 8b provided with pick-up nozzles 7a, 7b on their tips and movable in X, Y directions, and magazine discharge stages 9a, 9b. Wafer 4 is stuck on an adhesive sheet, and diced. Each of diced pieces becomes a chip component C. Chip components C are delaminated from adhesive tapes by pick-up nozzles 7a, 7b. Chip components C picked up by pick-up nozzles 7a, 7b are carried to chip sliders 10a, 10b provided to chip component mounting section 3, by carrier tools 8a, 8b. Magazines 5, from which chip components C are picked up and which become empty, are distributed to magazine discharge stages 9a, 9b which are adjacent to pick-up stages 6a, 6b. A plurality of magazines 5 are stacked on and supplied to pick-up stages 6a, 6b, and when magazines 5 empty with chip components C move to magazine discharge stages 9a, 9b, lower-side magazines 5 are lifted up and supplied in order.

Chip component mounting section 3 comprises chip sliders 10a, 10b, carrier rails 11a, 11b carrying chip components C carried to chip sliders 10a, 10b to bonding tools 12a, 12b, bonding tools 12a, 12b retaining chip components by suction and mounting them on board 13, two-sight camera 14 recognizing images of alignment marks provided to circuit pattern P of circuit board 13 and alignment marks provided to chip components C, and board retaining stage 15 retaining circuit board 13 by suction.

As shown in FIG. 2, chip sliders 10a, 10b are plate-like members each having an L-shape as viewed from Y direction, the XY plane 101 of each plate-like member retains chip component C by suction, and the YZ plane 102 thereof is connected to carrier rail 11a or 11b by connecting member 103. Connecting member 103 is connected to ball screw 104 provided in carrier rail 11a or 11b, and chip slider 10a or 10b can be moved in Y direction by servomotor 105 connected to the ball screw. To XY plane 101 of chip slider 10a or 10b, a suction pump is connected through a tube (not shown), and it enables to retain chip component C by suction. Carrier rail 11a or 11b extend in Y direction, one end thereof is positioned at the side of chip component supply section 2, and the other end thereof is positioned at the side of bonding tool 12a or 12b. When chip component C is transferred from chip slider 10a or 10b to bonding tool 12a or 12b, it can be stopped at three positions of waiting position Wa or Wb which is positioned at the side of chip component supply section 2 of carrier rail 11a or 11b, transferring position Ta or Tb which is positioned at the side of bonding tool 12a or 12b, and retreating position Ra or Rb for retreating during the operation of bonding tool 12a or 12b, as shown in FIG. 1.

Referring to FIG. 1 again, bonding tools 12a, 12b are provided to gantry frame 16. Gantry frame 16 is installed to machine table 17 so as to step over circuit board 13. Carrier rails 11a, 11b are fixed to columnar portions 110a, 110b of gantry frame 16. To beam portion 111 of gantry frame 16, as shown in FIG. 3(A), bonding tools 12a, 12b are attached via lifting/lowering tools 112a, 112b. Bonding tools 12a, 12b can be adjusted in position in θ direction, and can be lifted and lowered in Z direction. Lifting/lowering tools 112a, 112b are fixed to beam portion 111, and when bonding tools 12a, 12b mount chip components C on circuit board 13, the accuracy in the direction of Z axis can be ensured. Board retaining stage 15 mounted with chip components C is installed on machine table 17, and can be moved in X and Y directions.

Further, as shown in FIG. 14, distance sensor 211 can be attached to the side surface of each bonding tool 12a or 12b. Distance sensor 211 determines the mounting height of chip component C mounted on circuit board 13. Distance sensor 211 corresponds to the height detection means in the present invention. As distance sensor 211, a distance sensor utilizing an infrared laser ray, a distance sensor utilizing a ultrasonic wave signal, etc. can be applied. Further, a lifting/lowering means comprising a servomotor and a ball screw is used, and the signal of a position detector such as an encoder mounted on the servomotor may be utilized.

Further, in the relationship between board retaining stage 15 and bonding tools 12a, 12b, as shown in FIG. 3(B), the board retaining stage 15 may be structured so as not to be able to move in X direction, and the bonding tools 12a, 12b may be structured so as to be able to move in X direction. Where, as the relationship between board retaining stage 15 and bonding tools 12a, 12b, as long as a relative movement in X and Y directions is possible, a relationship of any of the combinations may be employed. Further, even with supply of chip components C, instead of use of ship sliders 10a, 10b, a structure may be employed wherein bonding tools 12a, 12b directly move up to chip component supply section 2 and pick chip components C up.

Next, circuit board 13 retained by suction by board retaining stage 15 will be explained using FIG. 4. FIG. 4 shows a state viewing board 13 from the upper side in Z direction in FIG. 1. A plurality of circuit patterns P are formed on circuit board 13. Circuit patterns P are disposed at a condition lined up lengthwise and crosswise in X and Y directions. Chip components C are mounted on circuit patterns P. The mounting regions of chip components C on circuit board 13 are formed from a region where only bonding tool 12a can mount chip components C (exclusive mounting region SA), a region where only bonding tool 12b can mount chip components C (exclusive mounting region SB), and a region where both bonding tools 12a and 12b can mount chip components C (common mounting region KR).

FIG. 4 shows circuit board 13 where, when Y direction is referred to as “line”, exclusive mounting region SA has three lines, exclusive mounting region SB has three lines, and common mounting region KR has two lines. The mounting start lines of bonding tools 12a, 12b are indicated as mounting start lines Ja, Jb by arrows in FIG. 4. Respective bonding tools 12a, 12b start bonding operation from mounting start lines Ja, Jb, and mount chip components C in order on circuit patterns P. In case where a bad mark indicating a failure circuit pattern NG exists in the circuit patterns P, chip component C is not mounted and the mounting operation is transferred to an adjacent circuit pattern P. In case where the adjacent circuit pattern P is an end of a line being carried out with mounting, the mounting operation is transferred to a further adjacent line present at the side of common mounting region KR. Since the position of failure circuit pattern NG in the circuit patterns P is irregular and the number thereof is unknown, the timings of finish of the operations in exclusive mounting regions SA, SB of respective bonding tools 12a, 12b do not coincide with each other. At that time, without waiting for the finish of the mounting operation of the other, bonding tool 12a or 12b having finished the mounting operation in exclusive mounting region SA or SB starts the mounting of chip component C in common mounting region KR. By this, the waiting time up to the finish of the mounting operation of the other bonding tool 12a or 12b can be shortened, and the mounting operation onto circuit board 13 can be completed in a short time and the mounting tact time can be shortened. Where, the mounting tact time means a tact time required for mounting chip components C on a single circuit board 13.

Furthermore, if the information of failure circuit pattern NG in circuit board 13 is stored when chip components C are mounted, the operation for disposing failure circuit pattern NG under bonding tools 12a, 12b can be skipped, the mounting tact time can be shortened. Where, the operation for disposing failure circuit pattern NG under bonding tools 12a, 12b is an operation for adjusting in position board retaining stage 15 in X and Y directions, recognizing failure circuit pattern of circuit board 13 by two-sight camera 14, and determining not to mount chip component C thereon. Because the information of failure circuit pattern NG is stored in memory portion 51 of control section 50 in advance, these operations become unnecessary on failure circuit pattern NG, and the mounting tact time can be shortened. Where, the information of failure circuit pattern NG includes the coordinate information in circuit board 13, the layout information of circuit patterns P, etc.

Referring to FIG. 1 again, two-sight camera 14 is attached to beam portion 111 of gantry frame 16 at a condition capable of being moved in X, Y, Z and θ directions. The movement of two-sight camera 14 in X direction can be performed so as to move between bonding tools 12a and 12b along rail 113 provided on beam portion 111. Two-sight camera 14 is inserted between chip component C retained by suction by bonding tool 12a or 12b and circuit board 13, At the time of insertion, adjustment in X, Y, Z and θ directions is carried out. Then, the alignment mark provided on chip component C and the alignment mark provided on circuit pattern P of circuit board 13 are recognized in image. Based on the result of the image recognition, the position in θ direction of bonding tool 12a or 12b and the position of board retaining stage 15 in X and Y directions are adjusted.

Next, the operation of mounting apparatus 1 according to the present invention will be explained using the flowchart shown in FIG. 5 and the operation diagrams shown in FIGS. 6 to 12. In the flowchart, the respective operations of A surface side and B surface side shown in FIG. 1 are depicted separately. In the operation diagrams shown in FIGS. 6 to 12, mounting apparatus 1 shown in FIG. 1 is viewed from the upper side in Z axis, and referring chip component supply section 2 as an upper side and chip component mounting section 3 as a lower side, A surface side of circuit board 13 is depicted at a left side and B surface side of circuit board 13 is depicted at a right side. A part of carrier rails 11a, 11b, chip sliders 10a, 10b and two-sight camera 14 hidden by beam portion 111 are shown by dot lines.

First, the explanation will be started at a state where mounting apparatus 1 is in a condition shown in FIG. 6. FIG. 6 shows the state of steps ST01a to ST04a of the operations of A surface side and the state of steps ST01b to ST02b of the operations of B surface side shown in FIG. 5.

Concretely, in the A surface side, chip slider 10a is moved to waiting position Wa, and pick-up nozzle 7a picks up chip component C from wafer 4 and moves to waiting position Wa (step ST01a).

Further, board retaining stage 15 is driven, and circuit pattern P of circuit board 13 is moved to a position under bonding tool 12a (step ST02a).

Then, an alignment mark of chip component C retained by suction by bonding tool 12a and an alignment mark provided on circuit pattern P of circuit board 13 are recognized in image by two-sight camera 14 being moved to the side of bonding tool 12a (step ST03a).

The circuit pattern P to be a target for mounting becomes a circuit pattern P included in exclusive mounting region SA shown in FIG. 4. As the result of image recognition due to two-sight camera 14, in case where a bad mark is provided on circuit pattern P of circuit board 13 (step ST04a), it is recognized as failure circuit pattern NG and the operation is skipped to next circuit pattern P. The next circuit pattern P becomes an adjacent circuit pattern P or a circuit pattern P of an adjacent line. The skip operation becomes an operation in which chip component C is not mounted on circuit pattern P and board retaining stage 15 is driven so that the next circuit pattern P is positioned under bonding tool 12a (returned to step ST02a).

In B surface side, first, pick-up nozzle 7b picks up chip component C from wafer 4 in chip component supply section 2 (step ST01b).

Further, chip slider 10b, which has moved to transferring position Tb, transfers chip component C to bonding tool 12b (step ST02b).

Next, mounting apparatus 1 becomes the state shown in FIG. 7 from the state shown in FIG. 6. FIG. 7 shows states of steps ST05a to ST07a and steps of ST03b to ST04b shown in FIG. 5.

Concretely, in A surface side, based on the image recognition data obtained at step ST03a, alignment of bonding tool 12a in θ direction and alignment of board retaining stage 15 in X and Y directions are carried out (step ST05a). Then, two-sight camera 14 moves from A surface side to B surface side (step ST06a).

Further, chip component C is supplied to chip slider 10a having arrived at waiting position Wa from pick-up nozzle 7a (step ST07a).

In B surface side, pick-up nozzle 7b moves to waiting position Wb by carrier tool 8b (step ST03b). Then, chip slider 10b moves to waiting position Wb (step ST04b).

Next, mounting apparatus becomes from the state shown in FIG. 7 to the state shown in FIG. 8. FIG. 8 shows the state of ST08a to ST09a shown in FIG. 5.

Concretely, in A surface side, chip slider 10a moves to retreating position Ra (step ST08a). Successively, bonding tool 12a is lowered and presses and heats chip component C and mounts it on circuit pattern P of board 13 (step ST09a).

Next, mounting apparatus 1 becomes from the state shown in FIG. 8 to the state shown in FIG. 9. FIG. 9 shows the states of steps ST10a to ST11a and steps ST05b to ST06b shown in FIG. 5.

Concretely, in A surface side, if bonding tool 12 having completed the mounting of chip component C is lifted up, chip slider 10a moves to transferring position Ta (step ST10a). Further, pick-up nozzle 7a of chip component supply section 2 picks up chip component C from wafer 4 (step ST11a).

In B surface side, two-sight camera 14 moves to a position under bonding tool 12b (step ST05b). Successively, board retaining stage 15 is driven in X and Y directions, circuit pattern P of circuit board 13 is moved to the position under bonding tool 12b (step ST06b). The circuit pattern P to be a target for mounting becomes a circuit pattern P included in exclusive mounting region SB shown in FIG. 4.

Next, mounting apparatus 1 becomes from the state shown in FIG. 9 to the state shown in FIG. 10. FIG. 10 shows the states of steps ST12a to ST13a and steps ST07b to ST09b shown in FIG. 5.

Concretely, in A surface side, chip component C is transferred from chip slider 10a to bonding tool 12a (step ST12a). Then, pick-up nozzle 7a moves to waiting position Wa by carrier tool 8a (step ST13a).

In B surface side, the alignment mark provided on circuit pattern P of circuit board 13 being moved and the alignment mark of chip component C retained by suction by bonding tool 12b are recognized in image by two-sight camera 14 (step ST07b). As the result of the image recognition, in case where a bad mark is provided on circuit pattern P of circuit board 13 (step ST08b), it is recognized as failure circuit pattern NG and the operation is skipped to next circuit pattern P. The next circuit pattern P becomes an adjacent circuit pattern P or a circuit pattern P of an adjacent line. The skip operation becomes an operation in which chip component C is not mounted on circuit pattern P and board retaining stage 15 is driven so that the next circuit pattern P is positioned under bonding tool 12b (returned to step ST06b).

Further, at waiting position Wb, chip component C is transferred from pick-up nozzle 7b to chip slider 10b (step ST09b).

Next, mounting apparatus 1 becomes from the state shown in FIG. 10 to the state shown in FIG. 11. FIG. 11 shows the states of step ST14a and steps ST10b to ST11b shown in FIG. 5.

Concretely, in A surface side, chip slider 10a moves to waiting position Wa (step ST14a).

In B surface side, based on the image recognition data obtained at step ST07b, alignment of bonding tool 12b in θ direction and alignment of board retaining stage 15 in X and Y directions are carried out (step ST10b). Then, two-sight camera 14 moves from B surface side to A surface side (step ST11b).

Next, mounting apparatus 1 becomes from the state shown in FIG. 11 to the state shown in FIG. 12. FIG. 12 shows the states of step ST15a and steps ST12b to ST13b shown in FIG. 5.

Concretely, in A surface side, two-sight camera 14 moves to a position under bonding tool 12a (step ST15a).

In B surface side, chip slider 10b moves to retreating position Rb (step ST12b). Then, when the mounting, wherein bonding tool 12a is lowered and presses and heats chip component C having been retained by suction and mounts it on circuit pattern P of circuit board 13, is completed, bonding tool 12b is lifted up (step ST13b).

Next, in A surface side, the operation from step ST01a, at which chip slider 10a moves to waiting position Wa, is performed. Similarly, in B surface side, the operation from step ST01b, at which pick-up nozzle 7b picks up chip component C from wafer 4, is performed.

When the mounting of chip components C on circuit patterns P in exclusive mounting region SA of A surface side shown in FIG. 4 is completed, the mounting of chip components C on common mounting region KR is carried out. Similarly, when the mounting of chip components C on circuit patterns P in exclusive mounting region SB of B surface side is completed, the mounting of chip components C on common mounting region KR is carried out. Thus, both the operations for A surface side and B surface side are performed, during a time when one side performs mounting of chi components C, the other side completes the operation for supplying chip components C, and in accordance with the respective timings in completion of operation, board retaining stage 15 moves circuit board 13, and therefore, the mounting tact time of chip components C can be shortened.

Further, as shown in FIG. 4, if it is structured that common mounting region KR is disposed between exclusive mounting regions SA and SB and lines for starting mounting operation of chip components C are set at end portions of circuit board 13 (mounting start lines Ja and Jb shown in FIG. 4), as the mounting of chip components C proceeds, the distance to be moved with board retaining stage 15 from retaining circuit board 13 by suction can be made small, and the mounting tact time can be shortened.

Thus, although one of bonding tool 12a and 12b, which has completed the mounting operation on exclusive mounting region SA or SB earlier, performs the mounting operation on common mounting region KR, during the operation on common mounting region KR, if the other completes the mounting operation on exclusive mounting region SA or SB late, the bonding tool 12a or 12b completing late is controlled so as to also perform the mounting operation on common mounting region KR. By such a control, the bonding tool 12a or 12b, which has completed the mounting operation on exclusive mounting region SA or SB late, does not enter into a waiting state, and the mounting tact time can be shortened.

Furthermore, when the mounting of chip components C on circuit board 13 is completed, chip mounting heights (height of chip component C from circuit board 13) detected by distance sensor 211, which are stored in memory portion 51 of control section at the time of mounting, are summed up. The sum up is carried out for all chip components C mounted. After all chip components C are mounted on circuit board 13, in the next process, a batch press for pressing a plurality of chip components simultaneously is carried out. Therefore, at a condition where the number of chip components C carried out with the batch press (number of chip components at which a pressing tool for the batch press presses chip components at a time) is determined to be a unit, the dispersion of the mounting heights of chip components C is determined. As an example, a section of chip components C and circuit board 13 is shown in FIG. 15. In the case shown in FIG. 15, the number is shown as a number at which 8 chip components C1 to C8 can be served to the batch press. Further, PD in FIG. 15 shows a region where a pressing tool for the batch press presses chip components at a time. Heights H of chip components C from circuit board 13 are affected by dispersion in thickness of the wafer, and are dispersed as shown as H1 to H8 in FIG. 15. These height data H1 to H8 are stored in memory portion 51 of control section 50. In control section 50, it is determined whether the respective height data are within an acceptable range V of dispersion set in advance, and if it is determined to be out of the range, repair of chip component C at the corresponding position is demanded to an operator. Therefore, even if the mounting heights (thicknesses) of chip components C temporarily pressed onto circuit board 13 are dispersed, repair of chip component C is carried out, and in the main pressing process which is a next process, mounting failure can be prevented beforehand.

Further, when the mounting of chip components C onto circuit board 13 is completed, a state is realized wherein chip component is not mounted on failure circuit pattern NG. In the next process, the batch press where a plurality of chip components C are pressed simultaneously is carried out. Therefore, the pressing force may be varied so that the respective pressing forces applied to the respective chip components become uniform. As an example, the case shown in FIG. 16 will be explained. FIG. 16 is a sectional view showing a state where chip components C are not mounted on failure circuit patterns NG. Chip components C2, C4 which have not been mounted are shown by dot lines. In such a case, in the next process for batch press, if the batch press is carried out by a same pressing force as that to be applied at a state where chip components C1 to C8 are mounted, the pressing force applied to each of chip components C1, C3, C5 to C8 becomes greater than that applied at a usual condition. This causes mounting failure in the batch press. Therefore, concretely, the positions of chip components C mounted/unmounted on circuit board 13 and the number thereof are determined from the information of mounting positions of all chip components C mounted on circuit board 13 which is stored in memory portion 51 of control section 50. Next, the region of chip components C at the time of batch press performed in the next process (region PD shown in FIG. 16) is referred to as a unit, and the number of chip components C to be pressed is determined. Then, relative to a main pressing device in the next process, the information of the number of chip components C for each region is transmitted, thereby making the pressing force for main pressing variable. Therefore, even if there is a missing in chip components C temporarily pressed on circuit board 13, the pressing force for each chip component C can be maintained constant, and in the main pressing process which is the next process, mounting failure can be prevented.

### EXPLANATION OF SYMBOLS

1: mounting apparatus
2: chip component supply section
3: chip component mounting section
4: wafer
5: magazine
6a, 6b: pick-up stage
7a, 7b: pick-up nozzle
8a, 8b: carrier tool
9a, 9b: magazine discharge stage
10a, 10b: chip slider
11a, 11b: carrier rail
12a, 12b: bonding tool
13: circuit board
14: two-sight camera
15: board retaining stage
16: gantry frame
17: machine table
50: control section
51: memory portion
101: XY plane
102 YZ plane
103: connecting member
104: ball screw
105: servomotor
111: beam portion
113: rail
110a, 110b: columnar portion
112a, 112b: lifting/lowering tool
211: distance sensor
K: flexible film substrate
P: circuit pattern
C: chip component
NG: failure circuit pattern
SA, SB: exclusive mounting region
KR: common mounting region
Ja, Jb: mounting start line
Wa, Wb: waiting position
Ta, Tb: transferring position
Ra, Rb: retreating position

1. A mounting apparatus for mounting a chip component on a circuit pattern on a circuit board having a plurality of circuit patterns formed thereon, characterized in that a plurality of bonding tools, each of which mounts a chip component on each of said circuit patterns on said circuit board, are provided, and each bonding tool has, within a region on said circuit board where said chip component is to be mounted, an exclusive mounting region where only said each bonding tool can mount said chip component and a common mounting region where both said each bonding tool and an adjacent bonding tool can mount said chip component.

2. The mounting apparatus according to claim 1, wherein a failure circuit pattern in which a circuit pattern becomes a failure and a normal circuit pattern in which a circuit pattern is normal are included in said plurality of circuit patterns formed on said circuit board, and said each bonding tool has a function for mounting a chip component only on said normal circuit pattern on said circuit board based on information of said failure circuit pattern detected in advance.

3. The mounting apparatus according to claim 2, wherein a function is provided wherein said exclusive mounting region and said common mounting region of said each bonding tool are calculated from a positional information of said failure circuit pattern among said plurality of circuit patterns formed on said circuit board, and a chip component is mounted only on said normal circuit pattern on said circuit board based on an information of said calculated exclusive mounting region and common mounting region.

4. The mounting apparatus according to claim 2, wherein a carrier means is provided which, during a time when any of said plurality of bonding tools is mounting a chip component on said normal circuit pattern, supplies a chip component to any of remaining bonding tools among said plurality of bonding tools or supplies chip components to said remaining bonding tools.

5. The mounting apparatus according to claim 1, wherein a height detection means for detecting a mounting height of a chip component mounted on said circuit board is provided to said each bonding tool, and a function is provided wherein mounting heights of all chip components mounted on said circuit board are determined by said height detection means and dispersion of said mounting heights is calculated.

6. The mounting apparatus according to claim 1, wherein a function is provided wherein mounting positions of all chip components mounted on said circuit board are memorized, and said mounting positions and number of said chip components mounted on said circuit board and positions and number being unmounted are calculated.

7. A mounting method for mounting a chip component on a circuit pattern on a circuit board formed with a plurality of circuit patterns using a plurality of bonding tools, wherein an exclusive mounting region where only each bonding tool can mount said chip component and a common mounting region where both said each bonding tool and an adjacent bonding tool can mount said chip component are provided on said circuit board, and a failure circuit pattern in which a circuit pattern is a failure and a normal circuit pattern in which a circuit pattern is normal are included in said plurality of circuit patterns formed on said circuit board, said mounting method comprising the steps of:
a step at which each bonding tool starts to mount a chip component onto a normal circuit pattern within said exclusive mounting region; and
a step at which a chip component is mounted onto a normal circuit pattern within said common mounting region in order from a bonding tool which has finished mounting of a chip component onto a normal circuit pattern within each said exclusive mounting region.

8. The mounting method according to claim 7, further comprising:
a step at which a positional information of said failure circuit pattern among said plurality of circuit patterns formed on said circuit board is memorized in advance as a failure circuit pattern information; and
a step at which said exclusive mounting region and said common mounting region of said each bonding tool are calculated based on said failure circuit pattern information.

9. The mounting method according to claim 7, wherein a step is performed in parallel at which, during a time when any of said plurality of bonding tools is mounting a chip component on said normal circuit pattern, a chip component is carried to any of remaining bonding tools among said plurality of bonding tools or chip components are carried to said remaining bonding tools.

10. The mounting method according to claim 7, wherein a height detection means for detecting a mounting height of a chip component mounted on said circuit board is provided to said each bonding tool, said mounting method further comprising:
a step for determining mounting heights of all chip components mounted on said circuit board using said height detection means; and
a step for calculating dispersion of said mounting heights detected by said height detection means.

11. The mounting method according to claim 7, further comprising:
a step for memorizing mounting positions of all chip components mounted on said circuit board; and
a step for calculating said mounting positions and number of said chip components mounted on said circuit board and positions and number being unmounted.
